(19) United States
(12) Patent Application Publication
(10) Pub. No.: US 2017/0155373 A1
(43) Pub. Date: Jun. 1, 2017

(54) SURFACE ACOUSTIC WAVE (SAW) RESONATOR STRUCTURE WITH DIELECTRIC MATERIAL BELOW ELECTRODE FINGERS

(71) Applicant: Avago Technologies General IP (Singapore) Pte. Ltd., Singapore (SG)

(72) Inventors: Richard C. Ruby, Menlo Park, CA (US); Jyrki Kaitila, Riemerling (DE); Reed Parker, Saratoga, CA (US); Stephen Roy Gilbert, San Francisco, CA (US); John D. Larson, III, Palo Alto, CA (US)

(21) Appl. No.: 14/954,954

(22) Filed: Nov. 30, 2015

(51) Int. Cl. H03H 9/64; H03H 9/25

(52) U.S. Cl. CPC H03H 9/25

(57) ABSTRACT

A surface acoustic wave (SAW) resonator structure includes a substrate, a piezoelectric layer disposed on the substrate, and an interdigital transducer (IDT) electrode disposed over the piezoelectric layer. The IDT electrode includes multiple busbars and multiple electrode fingers extending from each busbar, where the electrode fingers are configured to generate surface acoustic waves in the piezoelectric layer. The SAW resonator structure further includes dielectric material disposed between the piezoelectric layer and at least at portion of the IDT. The dielectric material may be positioned below tips of the electrode fingers, thereby mass-loading the electrode fingers.

### BACKGROUND

Electrical resonators are widely incorporated in modern electronic devices. For example, in wireless communications devices, radio frequency (RF) and microwave frequency resonators are used in filters, such as filters having electrically connected series and shunt resonators forming ladder and lattice structures. The filters may be included in a duplexer (diplexer, triplexer, quadplexer, quintplexer, etc.) for example, connected between an antenna and a transceiver for filtering received and transmitted signals.

Various types of filters use mechanical resonators, such as surface acoustic wave (SAW) resonators. The resonators convert electrical signals to mechanical signals or vibrations, and/or mechanical signals or vibrations to electrical signals. FIG. 1A is a top plan view of a conventional SAW resonator structure 100, which includes an interdigital transducer (IDT) electrode 105 disposed on a piezoelectric layer 130. The IDT electrode 105 includes a first comb electrode 110 comprising a first busbar 115 and multiple first fingers 111-114 extending from the first busbar 115, and a second comb electrode 120 comprising a second busbar 125 and multiple second fingers 121-124 extending from the second busbar 125. The first fingers 111-114 extend in a first direction from the first busbar 115 (e.g., left to right in the illustrative orientation), and the second fingers 121-124 extend in a second direction, opposite the first direction, from the second busbar 125 (e.g., right to left in the illustrative orientation). Acoustic reflectors 104 are situated adjacent to the first and second busbars 115 and 125, respectively, on either end of an active region of the IDT electrode 105, which comprises the acoustic track between the first and second busbars 115 and 125.

FIGS. 1B and 1C are cross-sectional views of FIG. 1A of the conventional SAW resonator structure 100. In particular, FIG. 1B is a cross-section taken along reference line B-B′ of FIG. 1A, and FIG. 1C is a cross-sectional taken along reference line C-C′ of FIG. 1A. FIGS. 1B and 1C each show the piezoelectric layer 130 disposed on a substrate 102. FIG. 1B is a lateral view of each of the first fingers 111-114 and the second fingers 121-124, showing the interleaving pattern of the first and second comb electrodes 110 and 120. FIG. 1C is a longitudinal view of a representative electrode finger, first finger 112 extending from the first busbar 115, although the configurations of the other first fingers 111, 113 and 114 would be substantially the same. Likewise, the configuration of the second fingers 121-124 would be substantially the same as the first finger 112, except extending from the second busbar 125 in the opposite direction.

The piezoelectric layer 130 is formed on the substrate 102, which may be a hybrid silicon (Si)/lithium tantalate (LiTaO₃) (or LT) substrate. Such a hybrid Si/LT substrate confers certain advantages over a SAW resonator structure having a more conventional lithium tantalate (LT) or lithium niobate (LN) substrate, including better power handling, better pyro-electric properties, enhanced temperature compensation, higher quality factor Q (Q-factor) and higher coupling coefficient k². However, one drawback to using the hybrid Si/LT substrate is that plate mode “rattles” are created above the filter passband. Such rattles may interfere with carrier aggregation by having a “suck out” in the passband of another filter device.

Furthermore, in the SAW resonator structure 100, unwanted or spurious transverse modes are typically excited in addition to the desired leaky surface wave mode, occurring within a sagittal plane (e.g., indicated as sagittal plane 135 in FIG. 1A) of the SAW resonator structure 100. The sagittal plane includes both the surface normal and the propagation direction. These spurious transverse modes likewise create unwanted “suck-outs” within the filter passband of the SAW resonator structure 100, thereby degrading performance. Maximizing the leaky surface wave mode is desirable because it reduces the strength of the spurious transverse modes. Maximizing the desired leaky surface wave mode may also help to increase the effective coupling coefficient k² of the SAW resonator structure 100, as well as help better confine energy in the SAW resonator structure 100, leading to higher Q-values. All of these effects increase the performance of SAW resonator structure 100.

Therefore, a SAW resonator structure is needed that overcomes at least the above-mentioned shortcomings of conventional SAW resonator structures, such as reducing rattles, reducing the strength of spurious transverse modes, and maximizing desired leaky surface wave modes, for example.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals, refer to like elements.

FIG. 1A is a top plan view of a conventional SAW resonator structure.

FIG. 1B is a cross-sectional view of the conventional SAW resonator structure of FIG. 1A along line B-B′.

FIG. 1C is a cross-sectional view of the conventional SAW resonator structure of FIG. 2A along line C-C′.

FIG. 2A is a top plan view of a SAW resonator structure, according to a representative embodiment.

FIG. 2B is a cross-sectional view of the SAW resonator structure of FIG. 2A along line B-B′, according to a representative embodiment.

FIG. 2C is a cross-sectional view of the SAW resonator structure of FIG. 2A along line C-C′, according to a representative embodiment.

FIG. 3A is a top plan view of a SAW resonator structure, according to a representative embodiment.

FIG. 3B is a cross-sectional view of the SAW resonator structure of FIG. 3A along line B-B′, according to a representative embodiment.

FIG. 3C is a cross-sectional view of the SAW resonator structure of FIG. 3A along line C-C′, according to a representative embodiment.

FIG. 3D is a cross-sectional view of the SAW resonator structure of FIG. 3A along line C-C′, with tapered dielectric material edges, according to a representative embodiment.

FIG. 4A is a top plan view of a SAW resonator structure, according to a representative embodiment.

FIG. 4B is a cross-sectional view of the SAW resonator structure of FIG. 4A along line B-B′, according to a representative embodiment.

FIG. 4C is a cross-sectional view of the SAW resonator structure of FIG. 4A along line C-C′, according to a representative embodiment.

FIG. 5A is a top plan view of a SAW resonator structure with mass-loaded electrode finger tips, according to a representative embodiment.

FIG. 5B is a cross-sectional view of the SAW resonator structure of FIG. 5A along line B-B′, according to a representative embodiment.

FIG. 5C is a cross-sectional view of the SAW resonator structure of FIG. 5A along line C-C′, according to a representative embodiment.

FIG. 6A is a top plan view of a SAW resonator structure with mass-loaded electrode finger tips, according to a representative embodiment.

FIG. 6B is a cross-sectional view of the SAW resonator structure of FIG. 6A along line B-B′, according to a representative embodiment.

FIG. 6C is a cross-sectional view of the SAW resonator structure of FIG. 6A along line C-C′, according to a representative embodiment.

FIG. 7A is a top plan view of a SAW resonator structure with mass-loaded electrode finger tips, according to a representative embodiment.

FIG. 7B is a cross-sectional view of the SAW resonator structure of FIG. 7A along line B-B′, according to a representative embodiment.

FIG. 7C is a cross-sectional view of the SAW resonator structure of FIG. 7A along line C-C′, according to a representative embodiment.

FIG. 8A is a top plan view of a SAW resonator structure with mass-loaded electrode finger tips, according to a representative embodiment.

FIG. 8B is a cross-sectional view of the SAW resonator structure of FIG. 7A along line B-B′, according to a representative embodiment.

FIG. 8C is a cross-sectional view of the SAW resonator structure of FIG. 7A along line C-C′, according to a representative embodiment.

FIGS. 9A and 9B are alternative cross-sectional views of the SAW resonator structure of FIG. 5A, according to a representative embodiment.

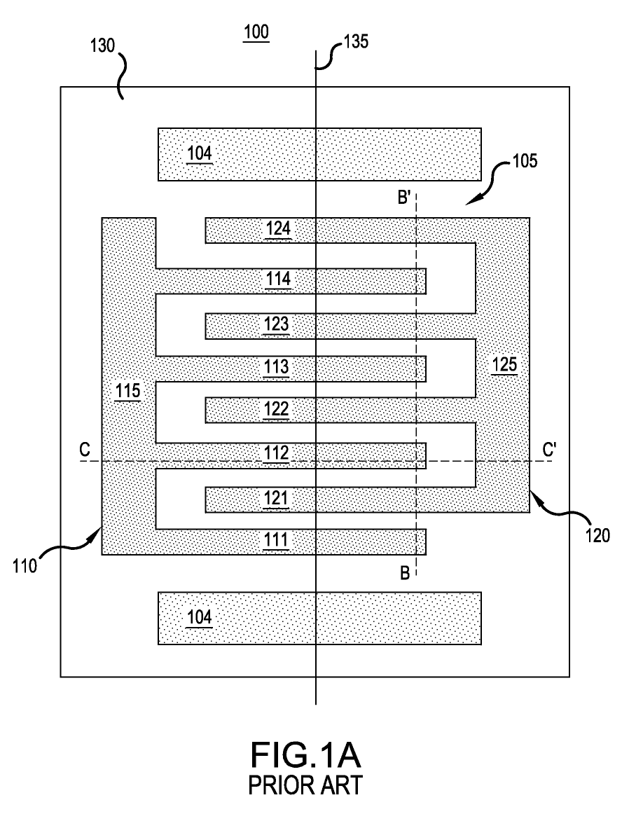

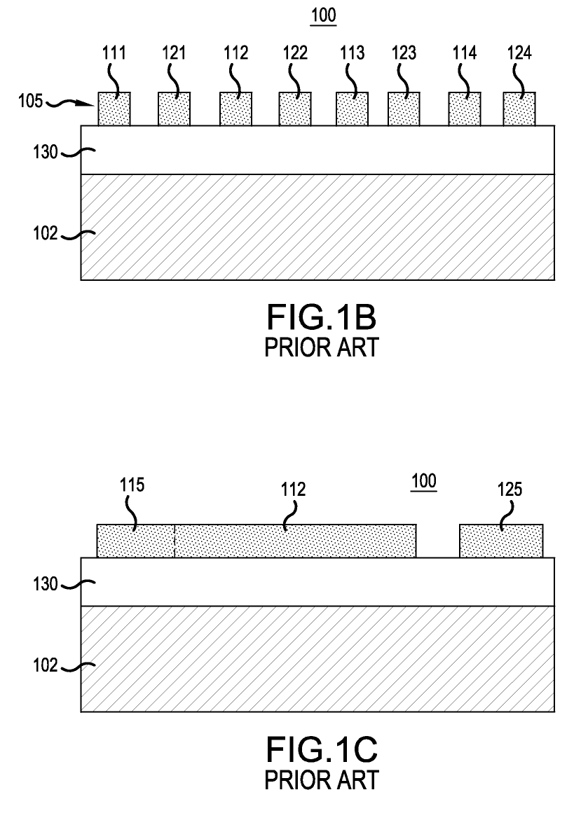

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, “a device” includes one device and plural devices.

As used in the specification and appended claims, and in addition to their ordinary meanings, the terms “substantial” or “substantially” mean to with acceptable limits or degree. For example, “substantially cancelled” means that one skilled in the art would consider the cancellation to be acceptable.

As used in the specification and the appended claims and in addition to its ordinary meaning, the term “approximately” means to within an acceptable limit or amount to one having ordinary skill in the art. For example, “approximately the same” means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

Generally, according to various embodiments, a surface acoustic wave (SAW) resonator structure includes a substrate, a piezoelectric layer disposed on the substrate, and an interdigital transducer (IDT) electrode disposed over the piezoelectric layer. The IDT electrode includes multiple busbars and multiple electrode fingers extending from each of the busbars, where the electrode fingers are configured to generate surface acoustic waves in the piezoelectric layer. The SAW resonator structure further includes dielectric material disposed between the piezoelectric layer and at least at portion of the IDT. In various embodiments, dielectric material is located below the tips of the electrode fingers, thereby mass-loading the tips.

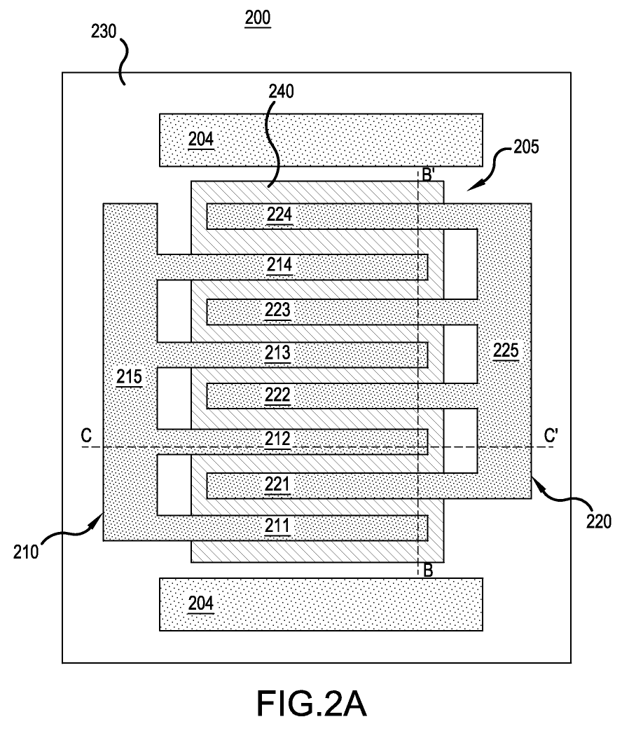

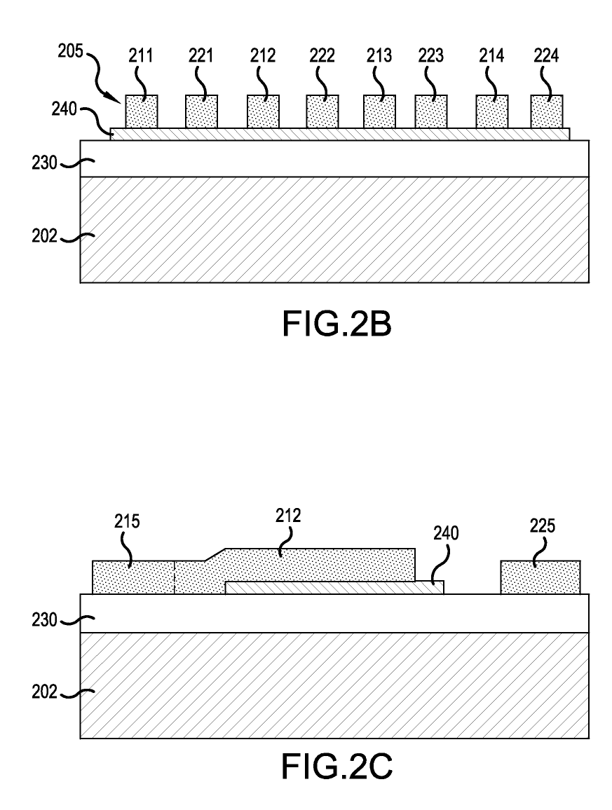

FIG. 2A is a top view of a SAW resonator structure 200, and FIGS. 2B and 2C are cross-sectional views of the SAW resonator structure 200 of FIG. 2A, according to a representative embodiment. Notably, the SAW resonator structure 200 (as well as the other SAW resonator structures discussed below according to the various embodiments) is intended to be merely illustrative of the type of device that can benefit from the present teachings. Other types of SAW resonator structures, including, but not limited to, a dual mode SAW (DMS) resonator structure, and structures therefore, are contemplated by the present teachings. The SAW resonator structures of the present teachings are also contemplated for a variety of applications. By way of example, a plurality of SAW resonator structures may be connected in a series/shunt arrangement to provide a ladder filter.

Referring to FIG. 2A, the SAW resonator structure 200 includes an interdigital transducer (IDT) electrode 205 disposed over a piezoelectric layer 230, which is disposed on a substrate 202 (not shown in FIG. 2A). The IDT electrode 205 includes a first comb electrode 210 comprising a first busbar 215 and multiple first fingers 211-214 extending from the first busbar 210, and a second comb electrode 220 comprising a second busbar 225 and multiple second fingers 221-224 extending from the second busbar 225. The first fingers 211-214 extend in a first direction from the first busbar 215 (e.g., left to right in the illustrative orientation), and the second fingers 221-224 extend in a second direction, opposite the first direction, from the second busbar 225 (e.g., right to left in the illustrative orientation). Acoustic reflectors 204 are situated adjacent to the first and second busbars 215 and 225, respectively, on either end of an active region of the IDT electrode 210. The active region of the IDT electrode 210 generally includes the overlapping interdigital portions of the first fingers 211-214 and the second fingers 221-224. The acoustic reflectors 204 are formed of the same material as the IDT electrode 205, for example, and generally are deposited at the same time. The acoustic reflectors 204 are configured to trap energy within the acoustic track of the SAW device.

Generally, the first fingers 211-214 of the first comb electrode 210 extend into corresponding spaces between the second fingers 221-224 of the second comb electrode 220, and the second fingers 221-224 of the second comb electrode 220 extend into corresponding spaces between the first fingers 211-214 of the first comb electrode 210, respectively. This arrangement forms an interleaving pattern, such that the IDT electrode 205 of the SAW resonator structure 200 is interdigital.

In addition, a thin layer of dielectric material 240 is disposed between the piezoelectric layer 230 and the portion of the IDT electrode 205 forming the interleaving pattern of the first fingers 211-214 and the second fingers 221-224 (which effectively corresponds to the active region of the IDT electrode 210). As shown, the dielectric material 240 is configured as a continuous layer formed below all of the first fingers 211-214 and the second fingers 221-224. The dielectric material 240 does not extend below the first and second busbars 215 and 225, respectively. In various embodiments, the dielectric material 240 has a thickness in a range of approximately 5 Å to approximately 1000 Å, for example, although the thickness of the dielectric material 240 may vary to provide unique benefits for any particular situation or to meet application specific design requirements of various implementations, as would be apparent to one skilled in the art.

Adding the layer of dielectric material 240 under the first fingers 211-214 and the second fingers 221-224 of the IDT electrode 205 reduces the coupling coefficient k² of the SAW resonator structure 200, which is advantageous for particular designs and applications. However, adding the layer of dielectric material 240 also serves to reduce the amplitude of the rattles. Also, the quality factor Q (Q-factor) improves, e.g., by up to about 40 percent, as more dielectric material 240 (that is, a thicker layer) is added between the piezoelectric layer 230 and the interdigital first and second fingers 211-214 and 221-224.

FIGS. 2B and 2C are cross-sectional views of FIG. 2A of the SAW resonator structure 200, according to a representative embodiment. In particular, FIG. 2B is a cross-section taken along reference line B-B′ of FIG. 2A, and FIG. 2C is a cross-sectional taken along reference line C-C′ of FIG. 2A. FIGS. 2B and 2C each show the piezoelectric layer 230 disposed on a substrate 202. FIG. 2B is a lateral view of each of the first fingers 211-214 and the second fingers 221-224, showing the interleaving pattern of the first and second comb electrodes 210 and 220. The first and second fingers 211-214 and 221-224 are formed on the continuous layer of dielectric material 240, which is disposed on the top surface of the piezoelectric layer 230.

FIG. 2C is a longitudinal view of the first finger 212 extending from the first busbar 215, which is representative of the first and second fingers 211-214 and 221-224. That is, the configurations of the other first fingers 211, 213 and 214 would be substantially the same as that of the depicted first finger 212. Likewise, the configurations of the second fingers 221-224 would be substantially the same as the first finger 212, except extending from the second busbar 225 in the opposite direction. The first finger 212 is in contact with the busbar 215, and extends away from the busbar 215 across a center region of the SAW resonator structure 200. A first section of the first finger 212 (e.g., the left side in the illustrative orientation), in contact with the first busbar 215, is disposed on the top surface of the piezoelectric layer 230, and the remainder of the first finger 212 extends over the top surface of the dielectric material 240. In the depicted embodiment, both the first and second busbars 215 and 225 are disposed on the top surface of the piezoelectric layer 230.

In the various embodiments, the substrate 202 may be formed of a material compatible with semiconductor processes, such as polycrystalline silicon, monocrystalline silicon, glass, polycrystalline aluminum oxide (Al₂O₃), monocrystalline aluminum oxide (Al₂O₃), silicon (Si), gallium arsenide (GaAs), or indium phosphide (InP), for example. Of course, other materials may be incorporated, without departing from the scope of the present teachings.

The piezoelectric layer 230 may be formed may be formed of any piezoelectric material compatible with resonator processes, such as lithium niobate (LiNbO3) (LN) or lithium tantalate (LiTaO3) (LT), aluminum nitride (AlN), zinc oxide (ZnO), or lead zirconate titanate (PZT), for example. Of course, other materials may be incorporated, without departing from the scope of the present teachings. Also, in various embodiments, piezoelectric layer 230 may be “doped” with at least one rare earth element, such as scandium (Sc), yttrium (Y), lanthanum (La), or erbium (Er), for example, to increase the piezoelectric coupling coefficient e33 in the piezoelectric layer 230, thereby off-setting at least a portion of any reduction of the coupling coefficient k². Examples of doping piezoelectric layers with one or more rare earth elements for improving electromechanical coupling coefficient k² are provided by U.S. patent application Ser. No. 13/662,425 (filed Oct. 27, 2012), to Bradley et al., and U.S. patent application Ser. No. 13/662,460 (filed Oct. 27, 2012), to Grannen et al., which are hereby incorporated by reference in their entireties.

In various embodiments, the dielectric material 240 may comprise an oxide, such as silicon dioxide (SiO₂), aluminum oxide (Al2O3), phosphosilicate glass (PSG), or borosilicate glass (BSG), for example. However, other materials may be used as the dielectric material 240, such as silicon nitride (SiN) or non-conductive silicon carbide (SiC), for example, without departing from the scope of the present teachings. The above description of the dielectric material 240 equally applies to the other dielectric structures identified herein.

The first and second comb electrodes 210 and 220 may be formed of one or more electrically conductive materials, such as various metals compatible with semiconductor processes, including tungsten (W), molybdenum (Mo), iridium (Ir), aluminum (Al), gold (Au), platinum (Pt), ruthenium (Ru), niobium (Nb), and/or hafnium (Hf), for example. In various configurations, the first and second fingers 211-214 and 221-224 may be formed of the same or different material(s) than the first and second busbars 215 and 225. Also, the first and second comb electrodes 210 and 220 may be formed of two or more layers of electrically conductive materials, which may be the same as or different from one another. A thickness of each of the first and second fingers 211-214 and 221-224 may be in a range of about 1000 Å to about 6000 Å, and a thickness of each of the first and second busbars 215 and 225 may be in a range of about 0.5 um to about 2.0 um, for example. The above descriptions of the first and second comb electrodes 210 and 220 apply equally to the other comb electrodes identified herein, and therefore may not be repeated.

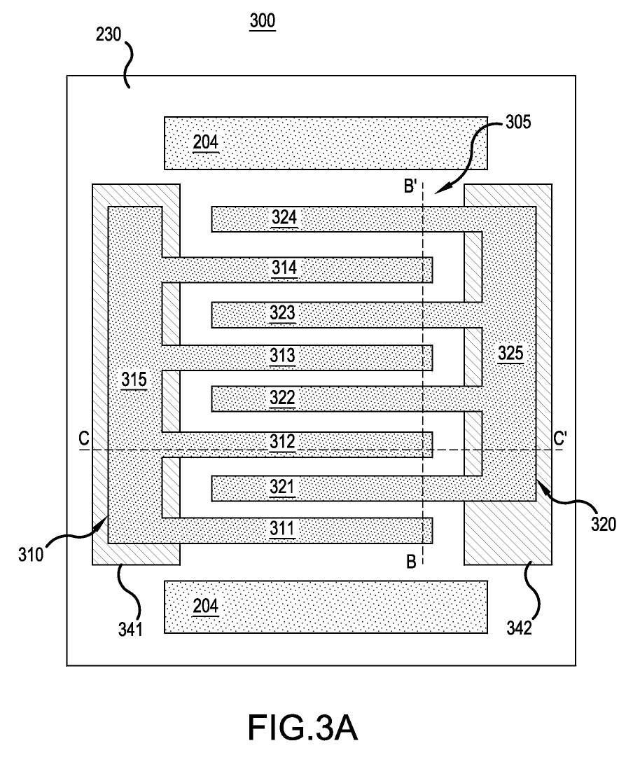

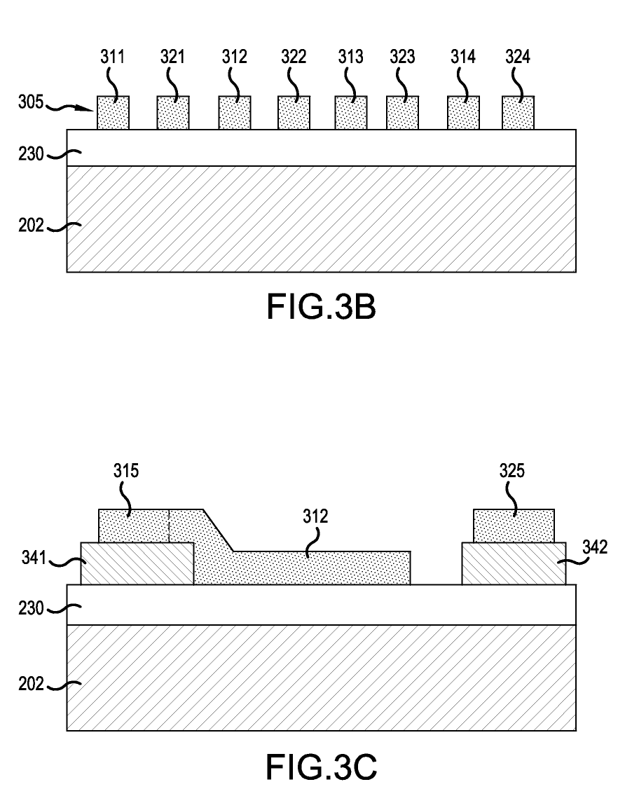

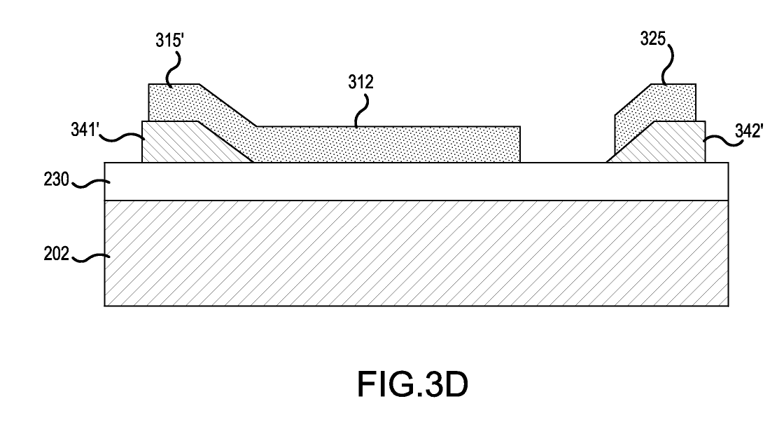

FIG. 3A is a top view of a SAW resonator structure 300, and FIGS. 3B and 3C are cross-sectional views of the SAW resonator structure 300 of FIG. 3A, according to a representative embodiment. FIG. 3D is also a cross-sectional view of the SAW resonator structure of FIG. 3A along line C-C′, with tapered edges of dielectric material below the busbars, according to a representative embodiment.

Referring to FIG. 3A, the SAW resonator structure 300 includes an IDT electrode 305 disposed over the piezoelectric layer 230, which is disposed on the substrate 202 (not shown in FIG. 3A). The IDT electrode 305 includes a first comb electrode 310 comprising a first busbar 315 and multiple first fingers 311-314 extending from the first busbar 310, and a second comb electrode 320 comprising a second busbar 325 and multiple second fingers 321-324 extending from the second busbar 325. The first fingers 311-314 extend in a first direction from the first busbar 315, and the second fingers 321-324 extend in a second direction, opposite the first direction, from the second busbar 325. The first fingers 311-314 extend into corresponding spaces between the second fingers 321-324, and the second fingers 321-324 of the second comb electrode 320 extend into corresponding spaces between the first fingers 311-314, respectively, forming an interleaving pattern, as discussed above.

In addition, dielectric material 341 is disposed between the piezoelectric layer 230 and the first busbar 315, and dielectric material 342 is disposed between the piezoelectric layer 230 and the second busbar 325. As shown, the dielectric material 341 is configured as a continuous layer formed below the dielectric material 341 and the dielectric material 342 is configured as a continuous layer formed below the dielectric material 342. Neither the dielectric material 341 nor the dielectric material 342 extends below the first fingers 311-314 or the second fingers 321-324, respectively, which are formed on the top surface of the piezoelectric layer 230. In various embodiments, the dielectric material 341, 342 has a thickness in a range of approximately 50 Å to approximately 50000 Å (5 μm), for example, although the thickness of the dielectric material 341, 342 may vary to provide unique benefits for any particular situation or to meet application specific design requirements of various implementations, as would be apparent to one skilled in the art.

Adding the layers of dielectric material 341 and 342 under the first and second busbars 315 and 325, respectively, reduces the electric field applied to the piezoelectric layer 230 in the areas under the first and second busbars 315 and 325, thereby reducing the excitation of spurious modes that arise from piezoelectrically excited bulk modes. This, in turn, reduces the unwanted rattles under the first and second busbars 315 and 325.

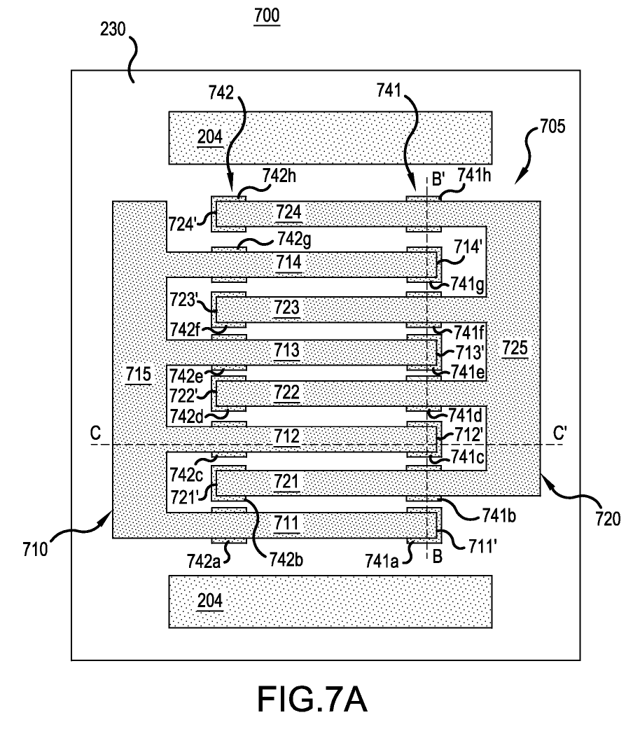

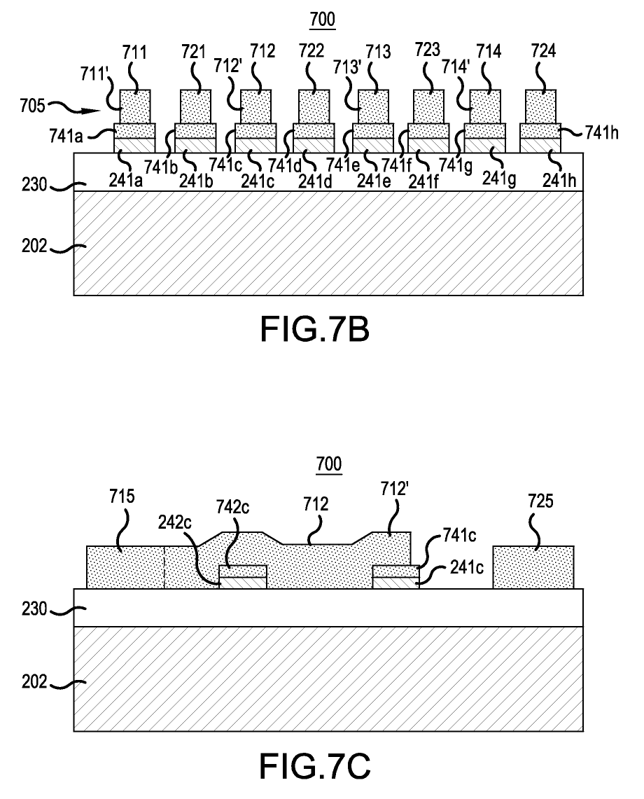

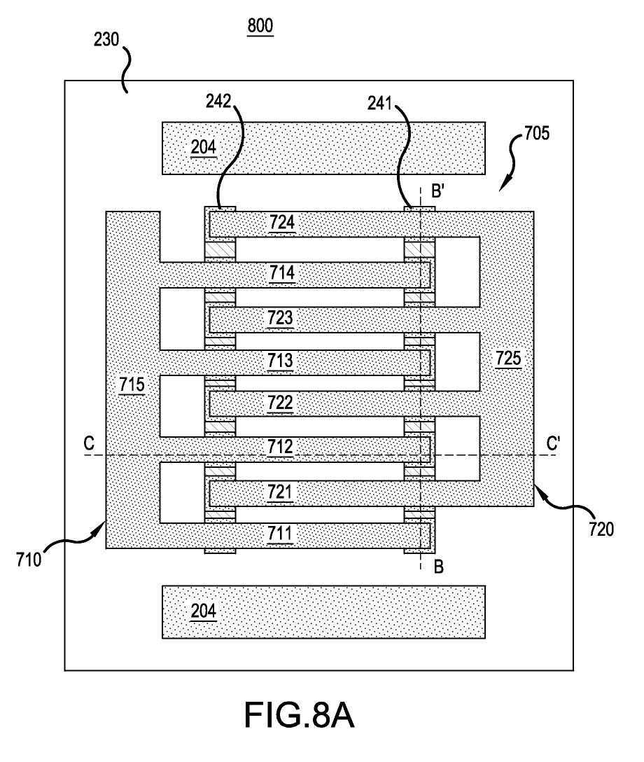

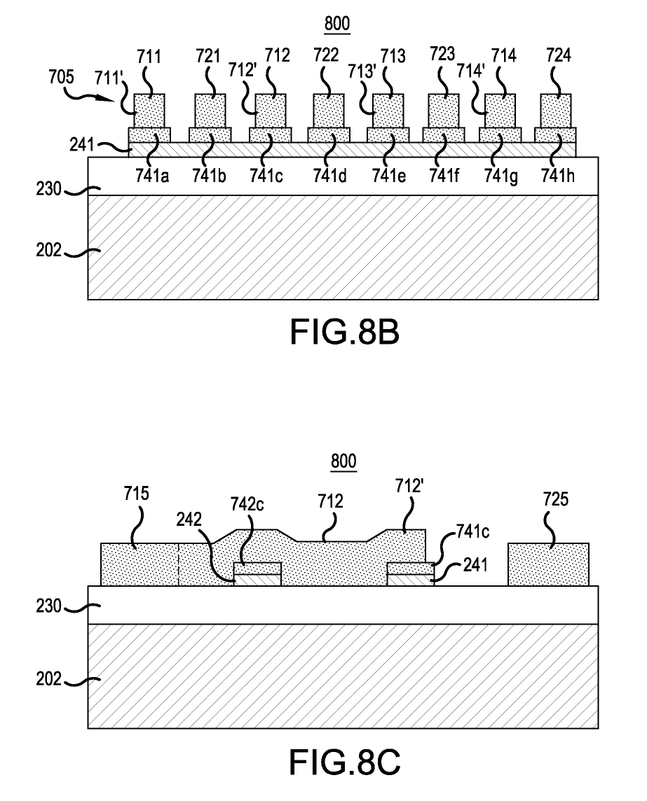

For example, in various embodiments, a layer of metal (e.g., aluminum (Al) or copper (Cu)) may be formed on the dielectric material 341, 342 (e.g., polyimide) below the first and second busbars 315 and 325, similar to the discussion below with reference to FIGS. 7A-7C and FIGS. 8A-8C, regarding the addition of metal layers to dielectric islands and/or strips below the electrode finger tips. The dielectric material 341 and 342 may be considered a first capacitor and the piezoelectric layer 230 (e.g., TL) may be considered a second capacitor, in series, forming a capacitive “electric field divider.” The “electrodes” of this capacitive electric field divider are the metal layer on top of the dielectric material 341, 342, and virtual ground formed by the substrate 202 (e.g., silicon (Si)) under the piezoelectric layer 230. By forming the dielectric material 341, 342 from a material having a low dielectric constant (e.g., polyimide or similar material having a relative dielectric constant of approximately 3), and forming it in a thick layer (e.g., about 5 μm), a small capacitance of the dielectric is created relative to the capacitance of the piezoelectric layer 230 (e.g., LT or similar material having a large relative dielectric constant of about 40) with a thickness of about 20 μm. In this configuration, the applied electric field mostly appears across the dielectric isolator capacitor, leaving only a small percentage of applied electric field to actually appear across the piezoelectric layer 230. This remaining portion of the applied electric field on the piezoelectric layer 230 drives the spurious “rattle” modes through the piezoelectricity of the piezoelectric layer 230. These are bulk modes of the first and second busbars 315 and 325 that appear at frequencies above the desired SAW passband, and may be minimized by reducing the electric field excitation on the first and second busbars 315 and 325. The dielectric material isolator is thus intended to minimize the electric field applied to the piezoelectric layer 230 immediately under the first and second busbars 315 and 325, and thus minimize one component of the spurious mode excitation.

FIGS. 3B and 3C are cross-sectional views of FIG. 3A of the SAW resonator structure 300, according to a representative embodiment. In particular, FIG. 3B is a cross-section taken along reference line B-B′ of FIG. 3A, and FIG. 3C is a cross-sectional taken along reference line C-C′ of FIG. 3A. FIG. 3B is a lateral view of each of the first fingers 311-314 and the second fingers 321-324, which are on the top surface of the piezoelectric layer 230 at the reference line B-B′. FIG. 3C is a longitudinal view of the first finger 312 extending from the first busbar 315, which is representative of the first and second fingers 311-314 and 321-324, as discussed above. The first finger 312 is in contact with the busbar 315 on the dielectric material 341. The first finger 312 extends away from the busbar 315, drops to the top surface of the piezoelectric layer 230 at the inner edge of the dielectric material 341, and further extends across a center region of the SAW resonator structure 300. In other words, a first section of the first finger 312 (in contact with the first busbar 315) is disposed on the top surface of the dielectric material 341, and the remainder of the first finger 312 extends over the top surface of the piezoelectric layer 230. In the depicted embodiment, the first and second busbars 315 and 325 are disposed on the top surfaces of the layers of dielectric material 341 and 342, respectively, as discussed above.

Also, in an embodiment, in place of the dielectric material 341 and 342 disposed between the piezoelectric layer 230 and the first and second busbars 315 and 325, the piezoelectric layer 230 may include ion implants below the first and second busbars 315 and 325, serving essentially the same purposes as the dielectric material 341 and 342. The ion implant regions of the piezoelectric layer 230 would effectively correspond to the hatched areas indicated by the reference numbers 341 and 342 shown in FIG. 3A (although no dielectric material would be present in these hatched areas). To form the ion implants, a pattern photoresist would be applied on the top of the piezoelectric layer 230 with openings in the hatched areas indicated by the reference numbers 341 and 342 shown in FIG. 3A. The wafer would then be ion implanted to damage or de-pole the piezoelectric material of the piezoelectric layer 230 in these ion implanted regions. The photoresist would then be stripped, and the patterned metal (e.g., the IDT electrode 305) would be applied. The ion implants suppress spurious modes coming from the first and second busbars 315 and 325, respectively, thereby reducing unwanted spurious modes under the first and second busbars 315 and 325.

FIG. 3D is a cross-sectional view of FIG. 3A of the SAW resonator structure 300, according to a representative embodiment. Referring to FIG. 3D, thick dielectric material 341′ and 342′ under first and second busbars 315′ and 325′, respectively, tapers down to about zero thickness, enabling the first and second fingers 311-314 and 321-324 of the IDT electrode 305 to more easily make contact with the first and second busbars 315′ and 325′, respectively. That is, the dielectric material 341′ and 342′ with tapered edges assists efficient step coverage. The dielectric material 341′ and 342′ also terminates the transverse electric field to minimize excitation of the transverse SAW wave.

In various embodiments, due to the significant thickness of the dielectric material 341, 342, as compared to the dielectric material below the first and second fingers of the IDT electrode, such as the dielectric material 240, the dielectric material 341, 342 may be formed of a polyimide. However, other materials may be used as the dielectric material 341, 342, such as an oxide, including silicon dioxide (SiO₂), aluminum oxide (Al₂O₃), phosphosilicate glass (PSG), or borosilicate glass (BSG), for example, silicon nitride (SiN) or non-conductive silicon carbide (SiC), for example, without departing from the scope of the present teachings.

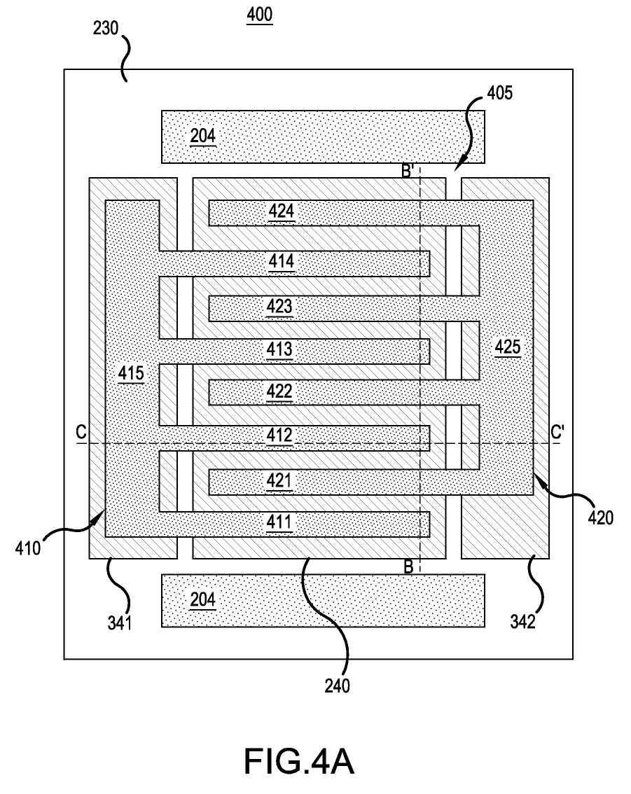

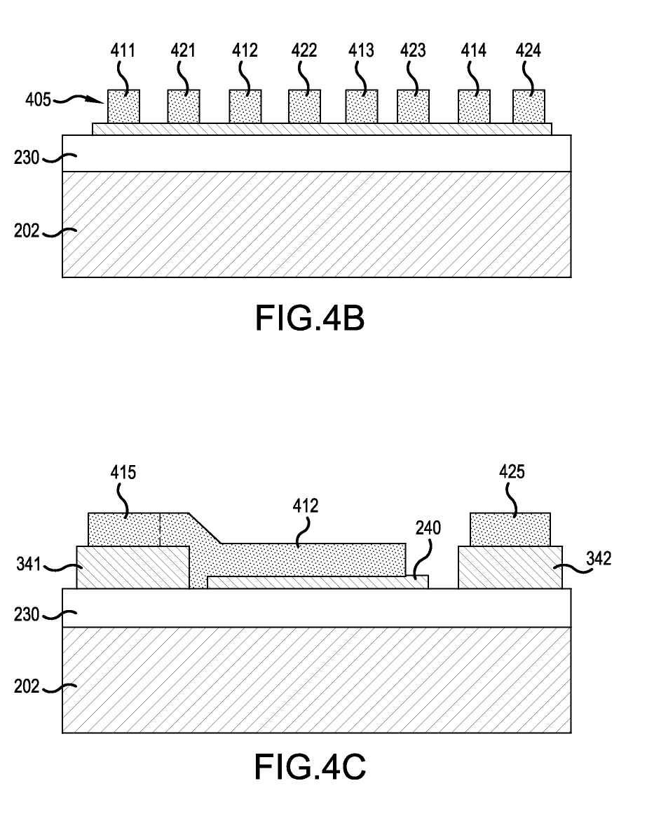

FIG. 4A is a top view of a SAW resonator structure 400, and FIGS. 4B and 4C are cross-sectional views of the SAW resonator structure 400 of FIG. 4A, according to a representative embodiment.

Referring to FIG. 4A, the SAW resonator structure 400 includes an IDT electrode 405 disposed over the piezoelectric layer 230, which is disposed on the substrate 202 (not shown in FIG. 4A). The IDT electrode 405 includes a first comb electrode 410 comprising a first busbar 415 and multiple first fingers 411-414 extending from the first busbar 410, and a second comb electrode 420 comprising a second busbar 425 and multiple second fingers 421-424 extending from the second busbar 425. The first fingers 411-414 extend in a first direction from the first busbar 415, and the second fingers 421-424 extend in a second direction, opposite the first direction, from the second busbar 425. The first fingers 411-414 extend into corresponding spaces between the second fingers 421-424, and the second fingers 421-424 of the second comb electrode 420 extend into corresponding spaces between the first fingers 411-414, respectively, forming an interleaving pattern, as discussed above.

In addition, a thin layer of dielectric material 240 is disposed between the piezoelectric layer 230 and the portion of the IDT electrode 405 forming the interleaving pattern of the first fingers 411-414 and the second fingers 421-424, as described with reference to the SAW resonator structure 200. Also, dielectric material 341 is disposed between the piezoelectric layer 230 and the first busbar 415, and dielectric material 342 is disposed between the piezoelectric layer 230 and the second busbar 325, as described with reference to the SAW resonator structure 300. As shown, each of the layers of dielectric material 341 and 342 is thicker than the layer of dielectric material 240. The thicknesses (and relative thicknesses) of the dielectric material 341, 342 and the dielectric material 240 may vary to provide unique benefits for any particular situation or to meet application specific design requirements of various implementations, as would be apparent to one skilled in the art.

Having both the layer of dielectric material 240 and the layers of dielectric material 341 and 342 provides corresponding benefits of each. For example, the relatively thick layer of dielectric material 341 and 342 underneath the first and second bus bars 415 and 425, respectively, suppresses unwanted spurious modes, including the “rattles.” The relatively thin layer of dielectric material 240 underneath the first fingers 411-414 and the second fingers 421-424 reduces coupling coefficient in a controlled manner, which is desirable for some filter designs, and suppresses unwanted spurious modes, including the “rattles.”

FIGS. 4B and 4C are cross-sectional views of FIG. 4A of the SAW resonator structure 400, according to a representative embodiment. In particular, FIG. 4B is a cross-section taken along reference line B-B′ of FIG. 4A, and FIG. 4C is a cross-section taken along reference line C-C′ of FIG. 4A. FIG. 4B is a lateral view of the alternating first fingers 411-414 and second fingers 421-424 on the top surface of the dielectric material 240, which is on the top surface of the piezoelectric layer 230 at the reference line B-B′. FIG. 4C is a longitudinal view of the first finger 412 extending from the first busbar 415, which is representative of the first and second fingers 411-414 and 421-424, as discussed above. The first finger 412 is in contact with the busbar 415 on the dielectric material 341. The first finger 412 extends away from the busbar 415, drops to the top surface of the piezoelectric layer 230 at the inner edge of the dielectric material 341, and further extends over the dielectric material across a center region of the SAW resonator structure 400. In other words, a first section of the first finger 412 (in contact with the first busbar 415) is disposed on the top surface of the dielectric material 341, a second section of the first finger 412 is disposed on the top surface of the piezoelectric layer 230, and a third section of the first finger 412 is disposed on the top surface of the dielectric material 240. In the depicted embodiment, the first and second busbars 415 and 425 are disposed on the top surfaces of the layers of dielectric material 341 and 342, respectively.

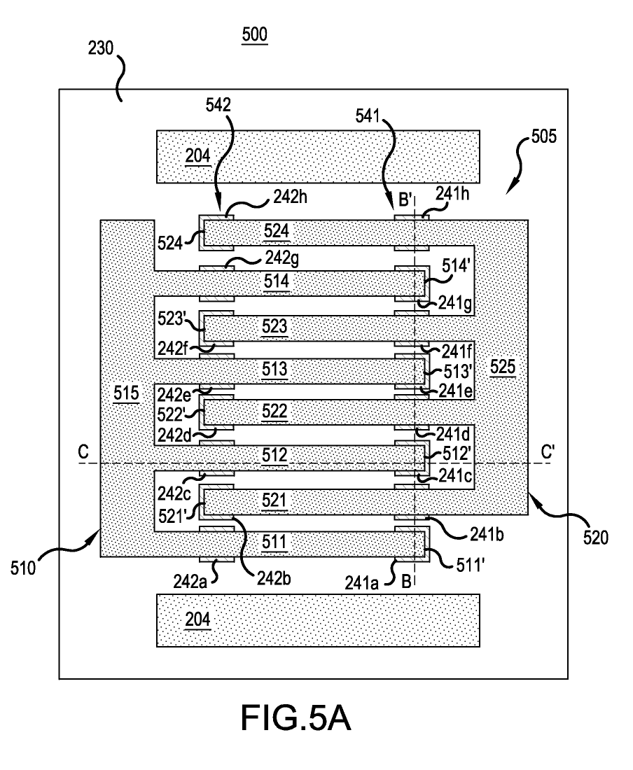

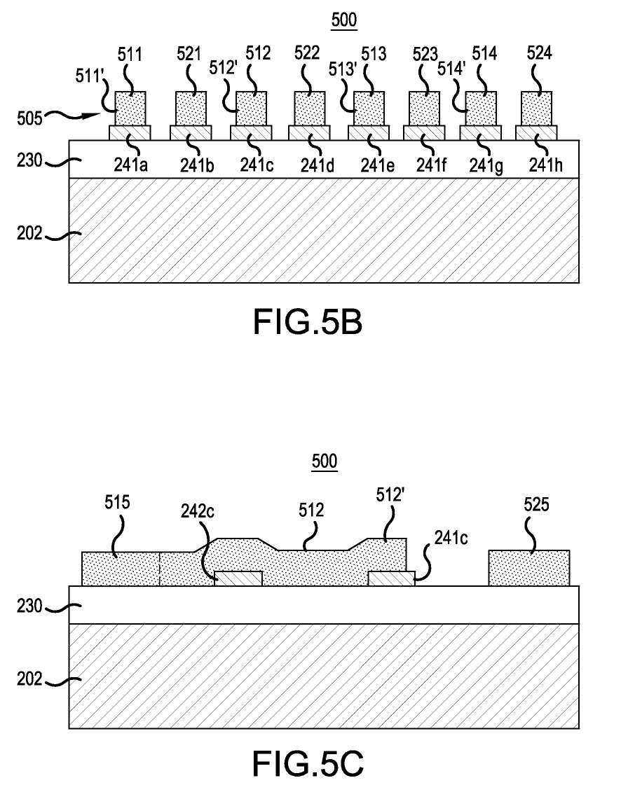

In the foregoing embodiments, including FIGS. 2A-4C, the interdigital first and second fingers of the IDT electrodes are applied to substantially flat or planar surfaces, particularly at the corresponding tips (or tip regions). In the following embodiments, including FIGS. 5A-9B, the tips of the first and second fingers are mass-loaded, respectively, meaning that the tips are thicker (e.g., in the vertical direction the depicted orientation of the cross-sectional views), when combined with the dielectric material, than the remaining portions of the first and second fingers. For purposes of discussion, the tip (or tip region) is the portion of an IDT electrode finger, extending from the outermost or distal end of the IDT electrode finger toward the corresponding busbar, within a range of about 5 percent to about 15 percent of the total length of the IDT electrode finger. Alternatively, or in addition, changes in width of the IDT electrode finger tip (e.g., as a percentage of the IDT electrode finger width) may be used to achieve desired control of coupling or reduction of rattle amplitude.

Mass-loading of the tips of the interdigital first and second fingers of an IDT electrode in a SAW resonator causes propagation velocity of acoustic tracks (or acoustic waves) under the corresponding thicker parts of the first and second fingers (including the dielectric material) to decrease. That is, the mass-loading of the tips will slow the SAW wave velocity in the tip region relative to that in the main region under the IDT electrode fingers. Generally, the purpose of the mass-loading is to tailor the boundary conditions of the IDT electrode fingers to limit the amount of energy lost outside the IDT structure. The presence of the dielectric material also reduces the coupling coefficient k² because some of the electric field is dropped across the dielectric material. Accordingly, by determining the proper dimensions (e.g., length, width and/or thickness) of the tips, the SAW resonator structure is able to force only the desired leaky surface wave mode within the sagittal plane of the IDT electrode.

In various embodiments, the IDT electrode tips are thickened to provide mass-loading using dielectric material applied between distal portions the first and second fingers of the IDT electrode and the underlying piezoelectric layer. This configuration reduces the effective coupling of the modes within the tip region, as well as reduces a transverse electric field in a direction perpendicular to a sagittal plane bisecting the interdigital electrode fingers. For example, the dielectric material applied below the tips of the first and second fingers may comprise a thin dielectric pad (or dielectric island) under each individual first and second finger tip, or a thin dielectric strip that extends across the piezoelectric layer under multiple first and second finger tips.

Using dielectric material underneath the electrode finger tips, the tips may be moved farther away from the piezoelectric layer, depending upon the dielectric thickness. This reduces effective coupling in the finger tip region, as mentioned above. Having less energy confined at the edges of the resonator should reduce the displacement and therefore the leakage at the end of the finger tips. In addition, the effective coupling at the edges is also reduced, so that a strong new lower frequency mode is not generated underneath the thin layer of dielectric material, thereby also improving the Q-values.

FIG. 5A is a top view of a SAW resonator structure 500, and FIGS. 5B and 5C are cross-sectional views of the SAW resonator structure 500 of FIG. 5A, according to a representative embodiment.

Referring to FIG. 5A, the SAW resonator structure 500 includes an IDT electrode 505 disposed over the piezoelectric layer 230, which is disposed on the substrate 202 (not shown in FIG. 5A). The IDT electrode 505 includes a first comb electrode 510 comprising a first busbar 515 and multiple first fingers 511-514 extending from the first busbar 510, and a second comb electrode 520 comprising a second busbar 525 and multiple second fingers 521-524 extending from the second busbar 525. The first fingers 511-514 extend in a first direction from the first busbar 515, and the second fingers 521-524 extend in a second direction, opposite the first direction, from the second busbar 525. The first fingers 511-514 extend into corresponding spaces between the second fingers 521-524, and the second fingers 521-524 extend into corresponding spaces between the first fingers 511-514, respectively, forming an interleaving pattern, as discussed above.

In addition, an island of dielectric material (referred to as a “dielectric island”) is disposed between the piezoelectric layer 230 and each tip (e.g., first tips 511′-514′ and second tips 521′-525′) or distal ends of each of the IDT electrode fingers (e.g., first fingers 511-514 and second fingers 521-524) forming the interleaving pattern of the IDT electrode 505. Each dielectric island is an isolated thin layer of dielectric material, meaning it is separate and otherwise not connected to other dielectric islands arranged on the piezoelectric layer 230. More particularly, referring to the first comb electrode 510, dielectric island 241a is disposed below the first tip 511′ of the first finger 511, dielectric island 241c is disposed below the first tip 512′ of the first finger 512, dielectric island 241e is disposed below the first tip 513′ of the first finger 513, and dielectric island 241g is disposed below the first tip 514′ of the first finger 514. Similarly, referring to the second comb electrode 520, dielectric island 242b is disposed below the second tip 521′ of the second finger 521, dielectric island 242d is disposed below the second tip 522′ of the second finger 522, dielectric island 242f is disposed below the second tip 523′ of the second finger 523, and dielectric island 242h is disposed below the second tip 524′ of the second finger 524.

In the depicted embodiment, in order to simplify fabrication, the dielectric islands 241a-241h and 242a-242h are formed in corresponding rows 541 and 542 of segmented dielectric material, where the dielectric islands 241a-241h and 242a-242h are spaced apart and located under the first and second fingers 511-514 and 521-524. Accordingly, each of the first and second fingers 511-514 and 521-524 is formed over a second dielectric island that is not at its tip, but rather is formed closer to the corresponding busbars 515 or 525 (respective proximal ends of the first and second fingers 511-514 and 521-524). More particularly, referring to the first comb electrode 510, dielectric island 242a is disposed below the first finger 511, dielectric island 242c is disposed below the first finger 512, dielectric island 242e is disposed below the first finger 513, and dielectric island 241g is disposed below the first finger 514. Similarly, referring to the second comb electrode 520, dielectric island 241b is disposed below the second finger 521, dielectric island 241d is disposed below the second finger 522, dielectric island 241f is disposed below the second finger 523, and dielectric island 241h is disposed below the second finger 524. However, in an alternative configuration, every other dielectric island of the row 541 (e.g., dielectric islands 241b, 241d, 241f and 241h) and of the row 542 (e.g., dielectric islands 242a, 241c, 241e and 241g) may be eliminated, so that only dielectric islands formed below the tips of the first and second fingers 511-514 and 521-524 are disposed on the piezoelectric layer 230.

In various embodiments, the dielectric material of each of the dielectric islands 241a-241h and 242a-242h has a thickness in a range of approximately 50 Å to approximately 1000 Å, for example, although the thickness of the dielectric material may vary to provide unique benefits for any particular situation or to meet application specific design requirements of various implementations, as would be apparent to one skilled in the art. Also, the thicknesses of the dielectric islands 241a-241h and 242a-242h in each row 541 and 542, respectively, are the same as one another, although in various alternative embodiments, the thicknesses of the dielectric islands 241a-241h in row 541 may be the same as or different from the thicknesses of the dielectric islands 242a-242h and in row 542.

FIGS. 5B and 5C are cross-sectional views of FIG. 5A of the SAW resonator structure 500, according to a representative embodiment. In particular, FIG. 5B is a cross-section taken along reference line B-B′ of FIG. 5A, and FIG. 5C is a cross-section taken along reference line C-C′ of FIG. 5A. FIG. 5B is a lateral view of the alternating first fingers 511-514 and second fingers 521-524 on the top surface of corresponding dielectric islands, which are formed on the top surface of the piezoelectric layer 230 at the reference line B-B′. The first tips 511′-514′ of the first fingers 511-514 are visible in the cross-section shown in FIG. 5B. Also, the first finger 511 is formed on the dielectric island 241a, the second finger 511 is formed on the dielectric island 241b, the first finger 512 is formed on the dielectric island 241c, the second finger 522 is formed on the dielectric island 241d, the first finger 513 is formed on the dielectric island 241e, the second finger 523 is formed on the dielectric island 241f, the first finger 514 is formed on the dielectric island 241g, and the second finger 524 is formed on the dielectric island 241h. Each of the dielectric islands 241a-241h is formed on the top surface of the piezoelectric layer 230. As discussed above, the first tips 511′-514′ of the first fingers 511-514 are mass-loaded by the dielectric islands 241a, 241c, 241e and 241g, respectively, e.g., causing propagation velocity of acoustic tracks under the mass-loaded first tips 511′-514′ to decrease.

FIG. 5C is a longitudinal view of the first finger 512 extending from the first busbar 515, which is representative of the first and second fingers 511-514 and 521-524, as discussed above. The first finger 512 is in contact with the busbar 515, which is formed on the top surface of the piezoelectric layer 230. In alternative configurations, the busbar 515 (and/or the busbar 525) may be formed on dielectric material, as discussed above with reference to FIGS. 3A-3C and FIGS. 4A-4C, without departing from the scope of the present teachings.

The first finger 512 extends away from the busbar 515, and is disposed on the top surface of the piezoelectric layer 230, as well as surfaces of the dielectric islands 242c and 241c. The tip 512′ of the first finger 512 is the distal portion of the first finger 512 on the dielectric island 241c. In other words, a first section of the first finger 512 (in contact with the first busbar 515) is disposed on the piezoelectric layer 230, a second section of the first finger 512 is disposed on the dielectric island 242c, a third section of the first finger 512 is disposed on the piezoelectric layer 230, and a fourth section (i.e., the tip 512′) of the first finger 512 is disposed on the dielectric island 241c.

As discussed above with reference to the dielectric material 240, the dielectric material forming the dielectric islands 241a-241h and 242a-242h may comprise an oxide, such as SiO₂, Al₂O₃, PSG, or BSG, for example. However, other materials may be used as the dielectric material, such as SiN or non-conductive SiC, for example, without departing from the scope of the present teachings.

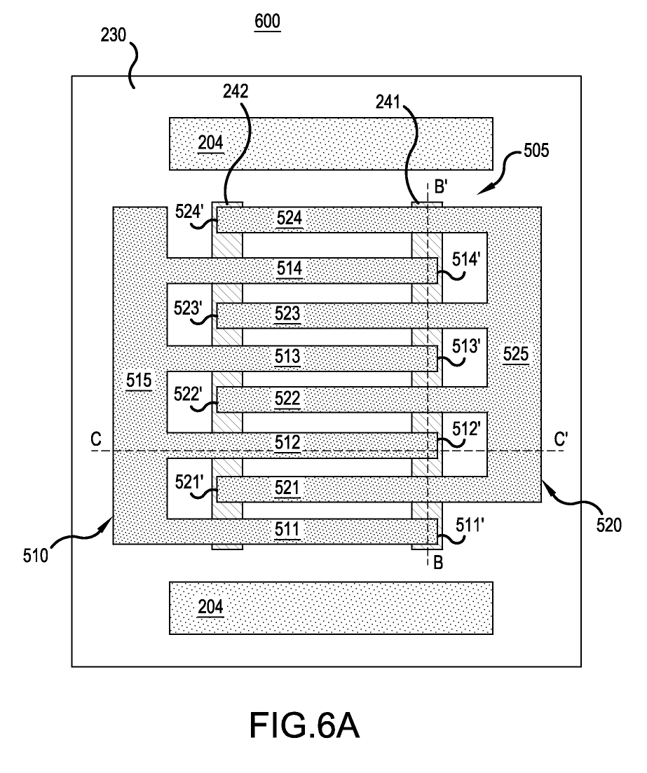

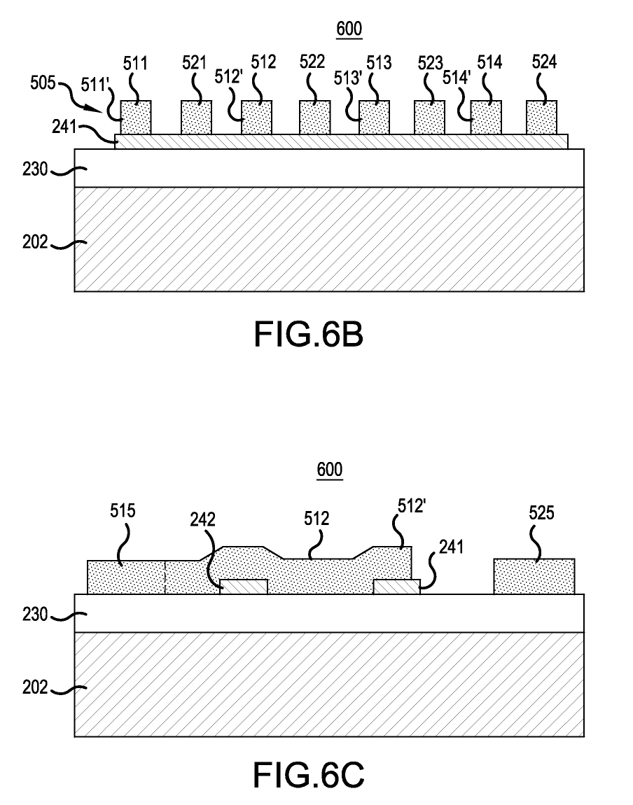

FIG. 6A is a top view of a SAW resonator structure 600, and FIGS. 6B and 6C are cross-sectional views of the SAW resonator structure 600 of FIG. 6A, according to a representative embodiment.

Referring to FIG. 6A, the SAW resonator structure 600 includes the IDT electrode 505 disposed over the piezoelectric layer 230, which is disposed on the substrate 202 (not shown in FIG. 6A). The IDT electrode 505 includes the first comb electrode 510 comprising the first busbar 515 and multiple first fingers 511-514 extending from the first busbar 510, and the second comb electrode 520 comprising the second busbar 525 and multiple second fingers 521-524 extending from the second busbar 525, as described above.

In addition, a strip of dielectric material, which may be referred to herein as a “dielectric strip,” is disposed between the piezoelectric layer 230 and the tips (e.g., first tips 511′-514′ and the second tips 521′-525′) of the IDT electrode fingers (e.g., first fingers 511-514 and second fingers 521-524) forming the interleaving pattern of the IDT electrode 505. More particularly, referring to the first comb electrode 510, dielectric strip 241 comprises a continuous thin layer of dielectric material disposed below the first tips 511′-514′ of the first fingers 511-514. Similarly, referring to the second comb electrode 520, dielectric strip 242 comprises a continuous thin layer of dielectric material disposed below the second tips 521′-524′ of the second fingers 521-524.

Because the dielectric strips 241 an 242 are continuous layers of dielectric material, they are also disposed below the alternating interdigital fingers, such that each of the first and second fingers 511-514 and 521-524 is formed over a second dielectric strip that is not at its tip, but rather is formed closer to the corresponding busbars 515 or 525 (respective proximal ends of the first and second fingers 511-514 and 521-524). More particularly, referring to the first comb electrode 510, the dielectric strip 242 is disposed below the first fingers 511-514 nearer the busbar 515, and referring to the second comb electrode 520, the dielectric strip 241 is disposed below the second fingers 521-524 nearer the busbar 525.

In various embodiments, the dielectric material of each of the dielectric strips 241 and 242 has a thickness in a range of approximately 50 Å to approximately 1000 Å, for example, although the thickness of the dielectric material may vary to provide unique benefits for any particular situation or to meet application specific design requirements of various implementations, as would be apparent to one skilled in the art. Also, in alternative embodiments, the thicknesses of the dielectric strips 241 and 242 may be the same as or different from one another. In yet other alternative embodiments, a SAW resonator structure may combine dielectric strips and dielectric islands. For example, a SAW resonator structure may include a dielectric strip 241 and a row 542 of dielectric islands 242a-242h, or alternatively, a dielectric strip 242 and a row 541 of dielectric islands 241a-241h, without departing from the scope of the present teachings.

FIGS. 6B and 6C are cross-sectional views of FIG. 6A of the SAW resonator structure 600, according to a representative embodiment. In particular, FIG. 6B is a cross-section taken along reference line B-B′ of FIG. 6A, and FIG. 6C is a cross-section taken along reference line C-C′ of FIG. 6A. FIG. 6B is a lateral view of the alternating first fingers 511-514 and second fingers 521-524 on the top surface of the dielectric strip 241, which is formed on the top surface of the piezoelectric layer 230 at the reference line B-B′. The first tips 511′-514′ of the first fingers 511-514 are visible in the cross-section shown in FIG. 6B. As discussed above, each of the first tips 511′-514′ of the first fingers 511-514 is mass-loaded by the portion of the dielectric strip 241 located under the corresponding first tip 511′-514′, e.g., causing propagation velocity of acoustic tracks under the mass-loaded first tips 511′-514′ to decrease.

FIG. 6C is a longitudinal view of the first finger 512 extending from the first busbar 515, which is representative of the first and second fingers 511-514 and 521-524, as discussed above. The first finger 512 is in contact with the busbar 515, which is formed on the top surface of the piezoelectric layer 230. In alternative configurations, the busbar 515 (and/or the busbar 525) may be formed on dielectric material, as discussed above with reference to FIGS. 3A-3C and FIGS. 4A-4C, without departing from the scope of the present teachings. The first finger 512 extends away from the busbar 515, and is disposed on the top surface of the piezoelectric layer 230, as well as surfaces of the dielectric strips 242 and 241. The tip 512′ of the first finger 512 is the distal portion of the first finger 512 on a portion of the dielectric strip 241. In other words, a first section of the first finger 512 (in contact with the first busbar 515) is disposed on the piezoelectric layer 230, a second section of the first finger 512 is disposed on the dielectric strip 242, a third section of the first finger 512 is disposed on the piezoelectric layer 230, and a fourth section (i.e., the tip 511′) of the first finger 512 is disposed on the dielectric strip 241. As discussed above with reference to the dielectric material 240, the dielectric material forming the dielectric strips 241 and 242 may comprise an oxide, such as SiO₂, Al₂O₃, PSG, or BSG, for example. However, other materials may be used as the dielectric material, such as SiN or non-conductive SiC, for example, without departing from the scope of the present teachings.

As discussed above, the structures at the first and second finger tips 511-514 and 521-524 of the IDT electrode 550 may be fabricated in the form of dielectric islands, dielectric strips, or some combination of both. Generally, to fabricate the SAW resonator structures 500 and 600, a dielectric layer is applied to the top surface of the piezoelectric layer 230. The dielectric layer is patterned, using a lift-off or etch process, for example, in combination with a first mask level. Next, the electrically conductive layer (e.g., metal layer) of the IDT electrode is formed with a second mask, using either a lift-off process or an etch process. Then, the thick pad and busbar metallization of the first and second busbars 515, 525 are formed using a third mask. Additional mask levels may be added before the metal layer of the IDT electrode if more than one patterned dielectric material or dielectric material thickness (e.g., dielectric islands 241a-241h and 242a-242h and/or dielectric strips 241 and 242) is needed below the first and second finger tips 511-514 and 521-524.

In various embodiments, a layer of metal may be formed on the dielectric material below the first and second fingers of the IDT electrode to contribute to mass-loading of the tips of the first and second fingers of the IDT electrode. For example, FIGS. 7A-7C, depicting a SAW resonator structure 700, are similar to FIGS. 5A-5C, depicting the SAW resonator structure 500, with the addition of a metal layer on each of the dielectric islands. That is, a layer of metal material, which may be referred to as a “metal pad,” is formed on each of the dielectric islands below the first and second fingers. Generally, the dielectric material at an electrode finger tip is mostly effective at reducing the coupling coefficient k², and less effective at reducing velocity. In comparison, the metal layer at the electrode finger tip has more of an effect on velocity. So, combining the dielectric material and the metal material at the electrode finger tips helps with both effects.

FIG. 7A is a top view of a SAW resonator structure 700, and FIGS. 7B and 7C are cross-sectional views of the SAW resonator structure 700 of FIG. 7A, according to a representative embodiment.

Referring to FIG. 7A, the SAW resonator structure 700 includes an IDT electrode 705 disposed over the piezoelectric layer 230, which is disposed on the substrate 202 (not shown in FIG. 7A). The IDT electrode 705 includes a first comb electrode 710 comprising a first busbar 715 and multiple first fingers 711-714 extending from the first busbar 710, and a second comb electrode 720 comprising a second busbar 725 and multiple second fingers 721-724 extending from the second busbar 725. The first fingers 711-714 extend in a first direction from the first busbar 715, and the second fingers 721-724 extend in a second direction, opposite the first direction, from the second busbar 725, forming an interleaving pattern with the first fingers 711-714, as discussed above.

The first and second fingers 711-714 and 721-724 are formed on metal pads stacked on respective dielectric islands. Referring to the first comb electrode 710, metal pad 741a and dielectric island 241a are disposed below the first tip 711′ of the first finger 711, metal pad 741c and dielectric island 241c are disposed below the first tip 712′ of the first finger 712, metal pad 741e and dielectric island 241e are disposed below the first tip 713′ of the first finger 713, and metal pad 741g and dielectric island 241g are disposed below the first tip 714′ of the first finger 714. Similarly, referring to the second comb electrode 720, metal pad 742b and dielectric island 242b are disposed below the first tip 721′ of the second finger 721, metal pad 742d and dielectric island 242d are disposed below the second tip 722′ of the second finger 722, metal pad 742f and dielectric island 242f are disposed below the second tip 723′ of the second finger 723, and metal pad 742h and dielectric island 242h are disposed below the second tip 724′ of the second finger 724. Other than the addition of the metal pads 741a-741h and 742a-742h, the SAW resonator structure 700 is substantially the same as the SAW resonator structure 500, the discussion of which applies equally to the SAW resonator structure 700.

In various embodiments, the dielectric material of each of the dielectric islands 241a-241h and 242a-242h has a thickness in a range of approximately 5 Å to approximately 1000 Å, for example, and the metal material of each of the metal pads 741a-741h and 742a-742h has a thickness in a range of approximately 50 Å to approximately 5000 Å, for example, although the thicknesses of the dielectric material and/or the metal material may vary to provide unique benefits for any particular situation or to meet application specific design requirements of various implementations, as would be apparent to one skilled in the art. In this case, the dielectric material may be thinner since the metal material provides much of the impact on desired velocity reduction. Also, the thicknesses of the dielectric islands 241a-241h and 242a-242h and the metal pads 741a-741h and 742a-742h in each row 741 and 742, respectively, may be the same or different from one another, respectively.

FIGS. 7B and 7C are cross-sectional views of FIG. 7A of the SAW resonator structure 700, according to a representative embodiment. In particular, FIG. 7B is a cross-section taken along reference line B-B′ of FIG. 7A, and FIG. 7C is a cross-section taken along reference line C-C′ of FIG. 7A. FIG. 7B is a lateral view of the alternating first fingers 711-714 and second fingers 721-724 on the top surface of corresponding metal pads stacked on dielectric islands, which are formed on the top surface of the piezoelectric layer 230. The first tips 711′-714′ of the first fingers 711-714 are visible in the cross-section shown in FIG. 7B. As discussed above, the first tips 711′-714′ of the first fingers 711-714 are mass-loaded by the combination of the metal pads 741a, 741c, 741e and 741g and the dielectric islands 241a, 241c, 241e and 241g, respectively. Generally, the combination of the metal pads in contact with the dielectric islands and the dielectric islands in contact with the piezoelectric layer provides enhanced reduction in both coupling coefficient k² and propagation velocity.

FIG. 7C is a longitudinal view of the first finger 712 extending from the first busbar 715, which is representative of the first and second fingers 711-714 and 721-724, as discussed above. The first finger 712 is in contact with the busbar 715, which is formed on the top surface of the piezoelectric layer 230. In alternative configurations, the busbar 715 (and/or the busbar 725) may be formed on dielectric material, as discussed above with reference to FIGS. 3A-3C and FIGS. 4A-4C, without departing from the scope of the present teachings. The first finger 712 extends away from the busbar 715, and is disposed on the top surface of the piezoelectric layer 230, as well as surfaces of the metal pads 742c and 741c (formed on the dielectric islands 242c and 241c, respectively). The tip 712′ of the first finger 712 is the distal portion of the first finger 712 on the metal pad 741c. In various embodiments, the metal pads 741a-741h and 742a-742h may be formed of one or more metal materials compatible with semiconductor processes, such as aluminum (Al) or copper (Cu). Of course, other materials may be incorporated, without departing from the scope of the present teachings.

Likewise, in place of metal pads on dielectric islands, alternative embodiments may include metal layers on dielectric strips, similar to the dielectric strips discussed above with reference to FIGS. 6A-6C. FIG. 8A is a top view of a SAW resonator structure 800, and FIGS. 8B and 8C are cross-sectional views of the SAW resonator structure 800 of FIG. 8A, according to a representative embodiment, in which metal layers are included on dielectric strips for mass-loading the tips of the first and second fingers of the IDT electrode.

Referring to FIG. 8A, the SAW resonator structure 800 includes an IDT electrode 705 disposed over the piezoelectric layer 230, which is disposed on the substrate 202 (not shown in FIG. 8A), as discussed above with reference to FIG. 7A. The first and second fingers 711-714 and 721-724 of the IDT electrode 705 are formed on metal pads stacked on respective dielectric strips. In particular, referring to the first comb electrode 710, the metal pads 741a, 741c, 741e and 741g formed on dielectric strip 241 are disposed below the first tips 711′-714′ of the first fingers 711-714, respectively, and referring to the second comb electrode 720, the metal pads 742b, 742d, 742f and 742h formed on dielectric strip 242 are disposed below the second tips 721′-724′ of the second fingers 721-724, respectively. Other than the addition of the metal pads 741a-741h and 742a-742h, the SAW resonator structure 800 is substantially the same as the SAW resonator structure 600, the discussion of which applies equally to the SAW resonator structure 800.

In various embodiments, the dielectric material of each of the dielectric strips 241 and 242 has a thickness in a range of approximately 50 Å to approximately 1000 Å, for example, and the metal material of each of the metal pads 741a-741h and 742a-742h has a thickness in a range of approximately 50 Å to approximately 5000 Å, for example, although the thicknesses of the dielectric material and/or the metal material may vary to provide unique benefits for any particular situation or to meet application specific design requirements of various implementations, as would be apparent to one skilled in the art. Also, the thicknesses of the dielectric strips 241 and 242 and the metal pads 741a-741h and 742a-742h may be the same or different from one another, respectively.

FIGS. 8B and 8C are cross-sectional views of FIG. 8A of the SAW resonator structure 800, according to a representative embodiment. In particular, FIG. 8B is a cross-section taken along reference line B-B′ of FIG. 8A, and FIG. 8C is a cross-section taken along reference line C-C′ of FIG. 8A. FIG. 8B is a lateral view of the alternating first fingers 711-714 and second fingers 721-724 on the top surfaces of the metal pads 741a-741h stacked on the dielectric strip 241, which is formed on the top surface of the piezoelectric layer 230. The first tips 711′-714′ of the first fingers 711-714 are visible in the cross-section shown in FIG. 7B. As discussed above, the first tips 711′-714′ of the first fingers 711-714 are mass-loaded by the combination of the stacked portion of the metal pads 741a, 741c, 741e and 741g and the dielectric strip 241 located under the corresponding first tip 711′-714′. Generally, the combination of the metal layers in contact with the dielectric strips, and the dielectric strips in contact with the piezoelectric layer provides enhanced reduction in both coupling coefficient k² and propagation velocity.

FIG. 8C is a longitudinal view of the first finger 712 extending from the first busbar 715, as discussed above. The first finger 712 is in contact with the busbar 715, which is formed on the top surface of the piezoelectric layer 230. In alternative configurations, the busbar 715 (and/or the busbar 725) may be formed on dielectric material, as discussed above with reference to FIGS. 3A-3C and FIGS. 4A-4C, without departing from the scope of the present teachings. The first finger 712 extends away from the busbar 715, and is disposed on the top surface of the piezoelectric layer 230, as well as surfaces of the metal pads 742c and 741c (formed on the dielectric strips 242 and 241, respectively). The tip 712′ of the first finger 712 is the distal portion of the first finger 712 on the metal pad 741c. In various embodiments, the metal pads 741a-741h and 742a-742h may be formed of one or more metal materials compatible with semiconductor processes, such as aluminum (Al) or copper (Cu). Of course, other materials may be incorporated, without departing from the scope of the present teachings.

In various alternative embodiments involving dielectric layers (e.g., dielectric islands or dielectric strips) under the first and second fingers of an IDT electrode, the dielectric layers may be formed to have tapered edges, similar to the tapered edges of the dielectric material under the busbars discussed above with reference to FIG. 3D, although the dielectric material under the first and second fingers are typically not as thick. The tapered edges improve adhesion of the subsequently applied electrically conductive material (e.g., metal), forming the first and second fingers and/or first and second busbars, to the dielectric material. Also, the tapered edges improve step coverage of metal that may be formed over those edges, respectively. The same is applicable with respect to tapering edges of metal pads or layers stacked on the dielectric islands or strips, respectively.

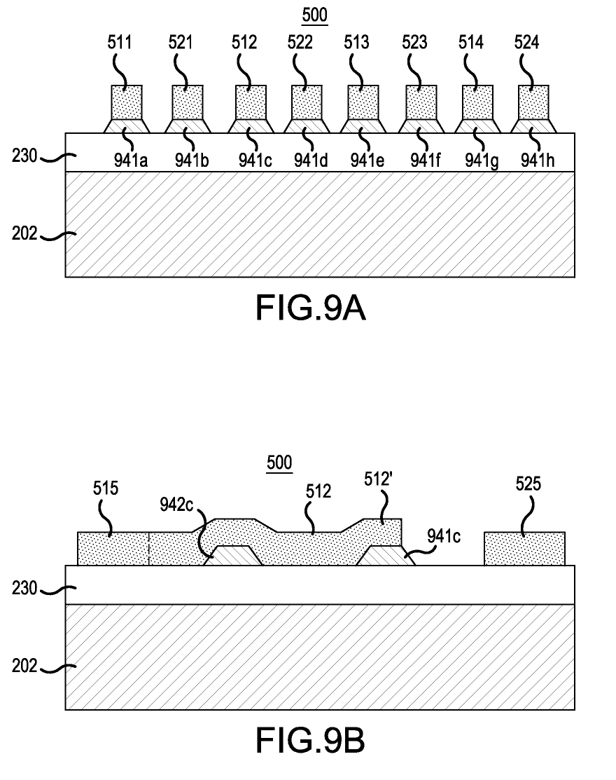

FIGS. 9A and 9B are alternative cross-sectional views of the SAW resonator structure 500 in FIG. 5A, according to a representative embodiment, in which the dielectric material applied below the first and second fingers has tapered edges. In particular, FIG. 9A is an alternative cross-section taken along reference line B-B′ of FIG. 5A, and FIG. 9B is an alterative cross-section taken along reference line C-C′ of FIG. 5A.

FIG. 9A is a lateral view of the alternating first fingers 511-514 and second fingers 521-524 on the top surfaces of corresponding dielectric islands 941a-941h, which are substantially the same as the dielectric islands 241a-241h, except with tapered edges. The first tips 511′-514′ of the first fingers 511-514 are visible in the cross-section shown in FIG. 9A. FIG. 9B is a longitudinal view of the first finger 512 extending from the first busbar 515, which is representative of the first and second fingers 511-514 and 521-524, as discussed above. The first finger 512 is in contact with the busbar 515, which is formed on the top surface of the piezoelectric layer 230. In alternative configurations, the busbar 515 (and/or the busbar 525) may be formed on dielectric material (e.g., also with tapered edges), without departing from the scope of the present teachings. The first finger 512 extends away from the busbar 515, and is disposed on the top surface of the piezoelectric layer 230, as well as surfaces of the dielectric islands 942c and 941c, which have tapered edges, as discussed above. The tip 512′ of the first finger 512 is the distal portion of the first finger 512 on the dielectric island 941c. Other configurations disclosed herein having dielectric layers may include tapered edges of the dielectric layers, as described above, without departing from the scope of the present teachings.

Also, in various alternative embodiments involving dielectric layers (e.g., dielectric islands or dielectric strips) for mass-loading the tips of the first and second fingers of an IDT electrode, the dielectric layers may be formed on top of the first and second fingers, as opposed to below the first and second fingers, without departing from the scope of the present teachings. Likewise, when metal layers (e.g., metal pads corresponding to dielectric islands) are incorporated for mass-loading the tips of the first and second fingers of an IDT electrode, the metal layers may be formed on top of the first and second fingers, as opposed to below the first and second fingers, without departing from the scope of the present teachings. For example, the dielectric layers may be formed under the tips of the first and second fingers, while the corresponding metal layers may be formed over the tips of the first and second fingers to provide mass-loading. Alternatively, both the dielectric layers and the metal layers formed on the dielectric layers may be formed over the tips of the first and second fingers to provide mass-loading.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A surface acoustic wave (SAW) resonator structure, comprising:
a substrate;
a piezoelectric layer disposed over the substrate;
an interdigital transducer (IDT) electrode disposed over the piezoelectric layer, the IDT electrode comprising a plurality of busbars and a plurality of electrode fingers extending from each busbar of the plurality of busbars, the plurality of electrode fingers being configured to generate surface acoustic waves in the piezoelectric layer; and
dielectric material disposed between the piezoelectric layer and at least a portion of the IDT electrode.

2. The SAW resonator structure of claim 1, wherein the dielectric material is disposed between the piezoelectric layer and the at least a portion of each of the plurality of electrode fingers, and not between the piezoelectric layer and the busbars.

3. The SAW resonator structure of claim 1, wherein the dielectric material is disposed between the piezoelectric layer and each of the plurality of busbars, and not between the piezoelectric layer and the plurality of electrode fingers extending from each busbar.

4. The SAW resonator structure of claim 3, wherein the dielectric layer disposed between the piezoelectric layer and each of the plurality of busbars reduces a portion of the coupling coefficient (k²) of the SAW resonator structure due to resonance in the plurality of busbars, and reduces occurrence of rattles trapped under the plurality of busbars.

5. The SAW resonator structure of claim 1, wherein the dielectric material is disposed between the piezoelectric layer and each of the busbars, and between the piezoelectric layer and the plurality of electrode fingers extending from each busbar.

6. The SAW resonator structure of claim 1, wherein the dielectric material is disposed below tips of the plurality of electrode fingers, respectively, thereby mass-loading the tips of the electrode fingers.

7. The SAW resonator structure of claim 6, wherein the dielectric material disposed below the tips of the electrode fingers comprises dielectric islands corresponding to the tips of the electrode fingers, respectively.

8. The SAW resonator structure of claim 6, wherein the dielectric material disposed below the tips of the electrode fingers comprises portions of at least one dielectric strip extending below tips of at least two electrode fingers.

9. The SAW resonator structure of claim 7, wherein the portions of the dielectric material disposed below the mass loaded tips reduce a coupling coefficient (k²) of the SAW resonator structure, and reduces a transverse electric field in a direction perpendicular to a sagittal plane bisecting the plurality of electrode fingers.

10. The SAW resonator structure of claim 7, wherein the portions of the dielectric material disposed below the mass loaded tips has a thickness of approximately 50 Å to approximately 1000 Å.

11. The SAW resonator structure of claim 1, further comprising:
at least one layer of metal disposed over the dielectric material, wherein portions of the dielectric material are disposed below tips of the plurality of electrode fingers, respectively, thereby mass-loading the tips of the electrode fingers.

12. The SAW resonator structure of claim 11, wherein the at least one metal layer is disposed on the dielectric material, such that both the corresponding portions of the dielectric material and the at least one metal layer are positioned below the mass loaded tips of the electrode fingers.

13. The SAW resonator structure of claim 11, wherein the at least one metal layer is disposed on the mass loaded tip of the electrode fingers and the corresponding portions of the dielectric material are disposed below the mass loaded tips of the electrode fingers.

14. The SAW resonator structure of claim 11, wherein the portions of the dielectric material comprise a dielectric island.

15. The SAW resonator structure of claim 6, wherein the portions of the dielectric material disposed below the mass loaded tips comprise dielectric islands or portions of a dielectric strip, and . wherein each of the dielectric islands or the dielectric strip comprises tapered edges.

16. The SAW resonator structure of claim 11, wherein the at least one metal layer comprises at least one of aluminum (Al) or copper (Cu).

17. The SAW resonator structure of claim 1, wherein the dielectric material comprises silicon dioxide (SiO₂), aluminum oxide (Al₂O₃), phosphosilicate glass (PSG), or borosilicate glass (BSG).

18. The SAW resonator structure of claim 3, wherein the dielectric material comprises silicon dioxide (SiO₂), aluminum oxide (Al₂O₃), phosphosilicate glass (PSG), borosilicate glass (BSG), or a polyimide.

19. The SAW resonator structure of claim 1, wherein the plurality of electrode fingers comprise aluminum (Al) or copper (Cu).

20. The SAW resonator structure of claim 1, wherein the piezoelectric layer comprises lithium niobate (LiNbO₃) (LN), lithium tantalate (LiTaO₃) (LT) or a silicon (Si)/lithium tantalate (LiTaO₃) hybrid.

21. The SAW resonator structure of claim 1, further comprising:
first and second reflectors disposed over the piezoelectric layer on opposite ends of the IDT electrode, wherein, when the dielectric material is disposed between the piezoelectric layer and at least a portion of each of the plurality of electrode fingers of the IDT electrode, the dielectric material is also disposed between piezoelectric layer and each of the first and second reflectors.

22. The SAW resonator structure of claim 2, wherein the piezoelectric layer includes an ion implant below each busbar of the plurality of busbars.

23. A surface acoustic wave (SAW) device including a plurality of SAW resonator structures, the SAW resonator structure comprising:
a piezoelectric layer disposed over a substrate;
a plurality of interdigital transducer (IDT) electrodes, respectively corresponding to the plurality of SAW resonator structures, each IDT electrode comprising a first busbar and a plurality of first fingers extending from the first busbar, and a second busbar and a plurality of second fingers extending from the second busbar in a direction opposite to the plurality of first fingers, the first and second fingers being configured to generate surface acoustic waves in the piezoelectric layer; and
dielectric material disposed between the piezoelectric layer and first and second tips of the first and second fingers of at least one IDT electrode of the plurality of IDT electrodes, thereby mass loading the first and second tips, respectively, wherein, in at least one other IDT electrode of the plurality of IDT electrodes, the first and second fingers have corresponding finger first and second tips that are not mass loaded by dielectric material.
